(19) United States
(12) Patent Application Publication
(10) Pub. No.: US 2007/0096133 A1
(43) Pub. Date: May 3, 2007

(54) System and method for LED manufacturing

(76) Inventors: Kian Shin Lee, Penang (MY); Meng Ee Lee, Penang (MY); Janet Bee Yin Chua, Perak (MY); Yew Cheong Kuan, Penang (MY)

Correspondence Address: AVAGO TECHNOLOGIES, LTD., P.O. BOX 1920, DENVER, CO, 80201-1920, US

(21) Appl. No.: 11/265,335

(22) Filed: Nov. 2, 2005

(51) Int. Cl. H01L 33/00

(52) U.S. Cl. 257/99

(57) ABSTRACT

An LED is formed using terminal leads that are rolled instead of die-set formed. Using this process, the terminal leads can end in several terminals thereby allowing higher heat dissipation. The LED can be produced using an LED chip that has light coming only from the top or with light coming from the sides as well. In one embodiment, the side emitting LED can have reflectors constructed within the device to reflect light to the top.

### TECHNICAL FIELD

This invention relates to LED manufacturing systems and methods and more particularly to LEDs manufactured with using roller formed terminals having increased heat dissipation.

### BACKGROUND OF THE INVENTION

Digital still cameras have come into widespread usage around the world. As their popularity grows, so does the need to make the cameras smaller, more versatile and, of course, less expensive. One vital function of all cameras is the need for a “flash” of light to illuminate subjects, particularly when the subject is in shadows or darkness.

Another function of a camera light source is to illuminate the subject to allow the camera to auto-focus its lens. This auto-focus light is less intense than the actual “flash” of light, but still must encompass the subject at varying focal lengths. Often, a single light source is called upon to perform multiple tasks, such as auto-focus, red-eye protection, timer alert and subject illumination (flash). Light emitting diodes (LEDs) having high brightness (usually greater than 10 cd), a narrow viewing angle and relatively inexpensive manufacturing are often used in such situations. The LED must have a long life and low current drain while maintaining an acceptable brightness level.

Typical prior art LED camera light sources use tie-bars to hold the pad to the LED chip while electrical leads are attached to each chip. These tie-bars then must be cut away during the singulation process. In addition, the electrical leads are formed using die sets which are expensive to make and maintain. These die-formed leads increase the physical size of the entire resulting structure.

A further problem is that existing LED electrical lead structures have high heat resistance and thus do not pass heat away from the junction as fast as desired if higher power is desired for increased brightness.

### BRIEF SUMMARY OF THE INVENTION

An LED is formed using terminals that are folded using roller techniques instead of die-set formed terminals and the LED is formed by molding a cover over the LED chip and the flat terminals. Using this process, the LED can have several heat conduction paths thereby allowing higher heat dissipation which in turn results in the ability to apply higher power levels to the LED if desired. The LED can be produced using a LED chip that has light coming only from the top or light coming from the sides as well. In one embodiment, the side emitting LED can have reflectors constructed within the device to reflect light to the top.

### BRIEF DESCRIPTION OF THE DRAWINGS

For a more complete understanding of the present invention, reference is now made to the following descriptions taken in conjunction with the accompanying drawings, in which:

FIG. 1A shows one embodiment of a molded LED device having flat multi-ends electrical terminals;

FIG. 1B shows one embodiment of the LED of FIG. 1A having internal side reflectors;

FIGS. 2A, 2B and 2C show one embodiment of the top, front and side views, respectively, of the molded structure of the LED of FIG. 1A;

FIG. 3 shows one embodiment of a flow chart of a manufacturing process for the LED of FIG. 1A;

FIG. 4 shows one embodiment of a device using the LED of FIG. 1A;

FIGS. 5A, 5B, 5C, 5D, 5E and 5F show one embodiment of LED terminal construction; and

FIGS. 6A, 6B, 7A, 7B, 7C, 7D, 7E, 7F, 7G, 7H, 7I and 7J show prior art LED construction.

### DETAILED DESCRIPTION OF THE INVENTION

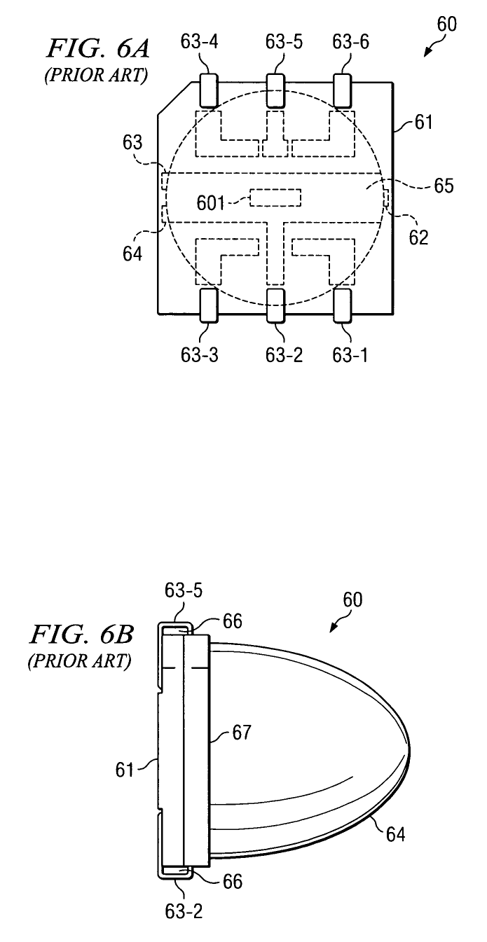

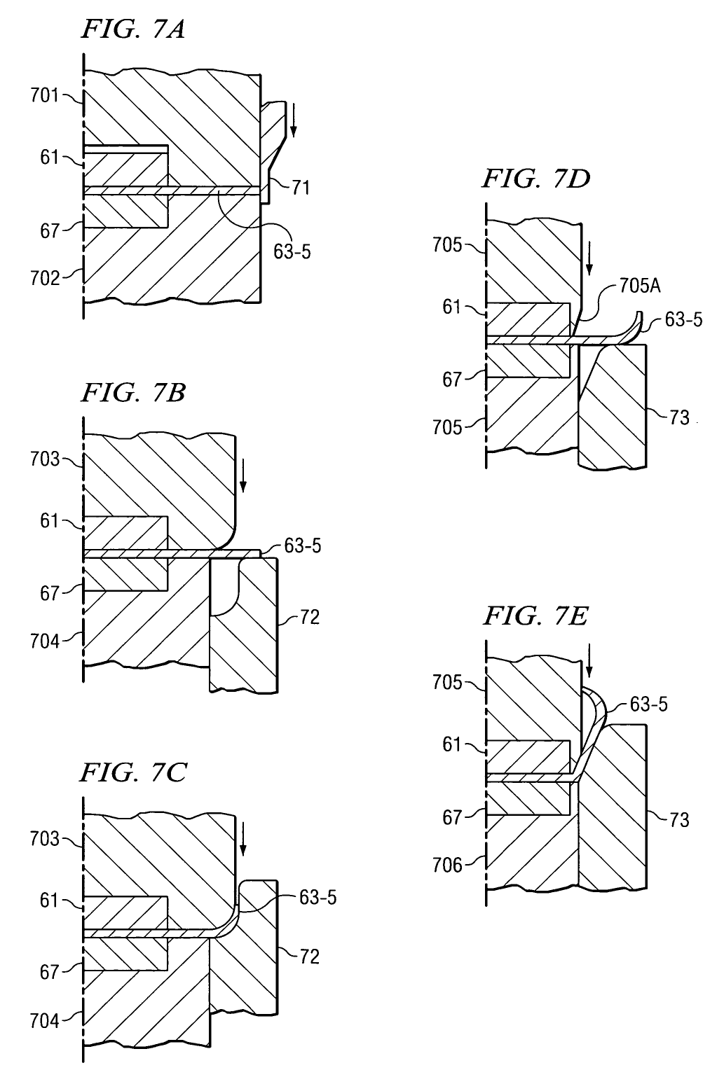

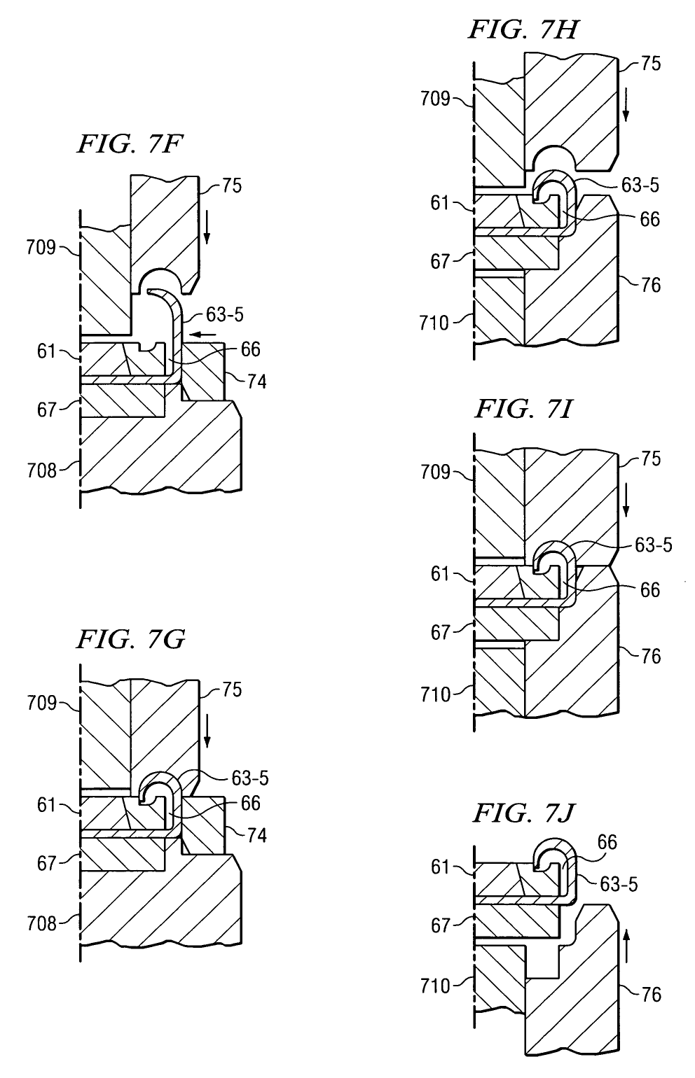

Prior to beginning a detailed description of the inventive concepts, it might be helpful to review prior art construction techniques with respect to FIGS. 6A and 6B. FIG. 6A shows device 60 having tie-bars 62, 63 and 64 surrounding the device to hold pad 65 in place during construction. LED dice 601 is held on pad 65. Device 60 has terminals 63-1, 63-2, 63-3, 63-4, 63-5 and 63-6 which are folded around the bottom of the device as shown and as discussed with respect to FIGS. 7A through 7J. While six terminals are shown, only two terminals, namely 63-2 and 63-5, make electrical contact with the die within the device. Terminal 63-2 is the only terminal available for heat dissipation when power is applied to the device since terminal 63-5 is connected to the LED chip by a wire trace. Tie-bars 62, 63, 64 are cut away during the singulation process, but certain portions of the tie-bar remain as part of the finished product. The extra four terminals (63-1, 63-3, 63-4 and 63-6) are used for mechanical stability during the manufacturing process, but are not electrically connected to the chip.

FIG. 6B shows a side view of device 60 with housing 64 and shows terminals 63-2 and 63-5 which were trimmed and formed using a die-set. Note gap 66 between body 61, 67 of the device and the terminal where the die tool (705, FIGS. 7D and 7E) was located for forming the terminal. The die wears easily and is expensive to manufacture and replace. In addition, its use increases the size of the entire package, primarily due to gap 66 needed for the die tool to sit when forming the terminal.

FIGS. 7A through 7J show a prior art method for forming terminals on LED devices. FIG. 7A shows terminal 63-5 extending from device portions 61 to 67 (as shown in FIG. 6B). Supports 701 and 702 are used to stabilize the LED device in the terminal and to support terminal 63-5 so that knife 71 can shear off the terminal at a desired length as shown.

FIG. 7B shows supports 703 and 704 put in place around the LED device to support the device and terminal 63-5, so that the end of the terminal can be bent upward, as shown in FIG. 7C, under control of die 72.

FIG. 7D shows that the LED device is now being supported by supports 705 and 706, with 705 having an end 705A used to support the bending, as shown in FIG. 7E, of terminal 63-5 under control of die 73. Note that end 705A forms gap 66 (as can be seen in FIG. 7F).

FIG. 7F shows the LED device now being held between stationary portion 708 and 709 while die 75 presses downward on terminal 63-5 as shown in FIG. 7G. Tool 74 is shown pushing inward to support terminal 63-5 as it is being positioned by tool 75. Note that gap 66 remains.

FIGS. 7H and 7I show the spanking process which finishes off the folding of terminal 63-5 pressing it into position under control of stationary portions 709, 710 and tool 76.

FIG. 7G shows the singulation process where the die is removed and the device separated from other devices.

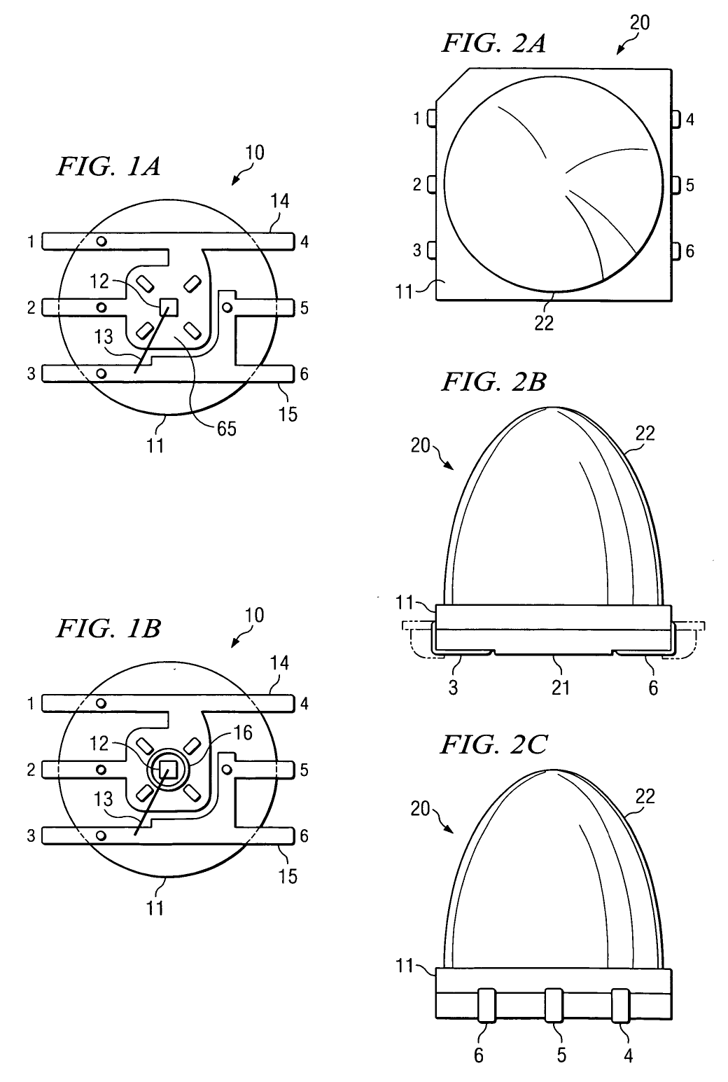

Turning now to FIG. 1A, there is shown a bottom view of LED device 10 utilizing the concepts taught herein. Housing 22 (shown in FIGS. 2A, 2B and 2C) has been removed for clarity. Note that there are two terminals, 14 and 15, each terminal having several ends such that terminal 14 has ends 1, 2 and 4 and terminal 15 has ends 3, 5 and 6. Terminal 14 contacts LED chip 12 directly, while terminal 15 is connected to LED chip 12 via wire (or trace) 13. Because terminal 14 (ends 1, 2 and 4) are electrically connected pad 65 upon which LED dice 12 sits and thus these terminals are available for the dissipation of heat thereby spreading the heat dissipation capability so as to increase the heat dissipation from the LED junction. Also note that no tie-bar exists in the package and that the dice is attached and held by terminal 14. Therefore there is no extra process needed to remove the tie-bar.

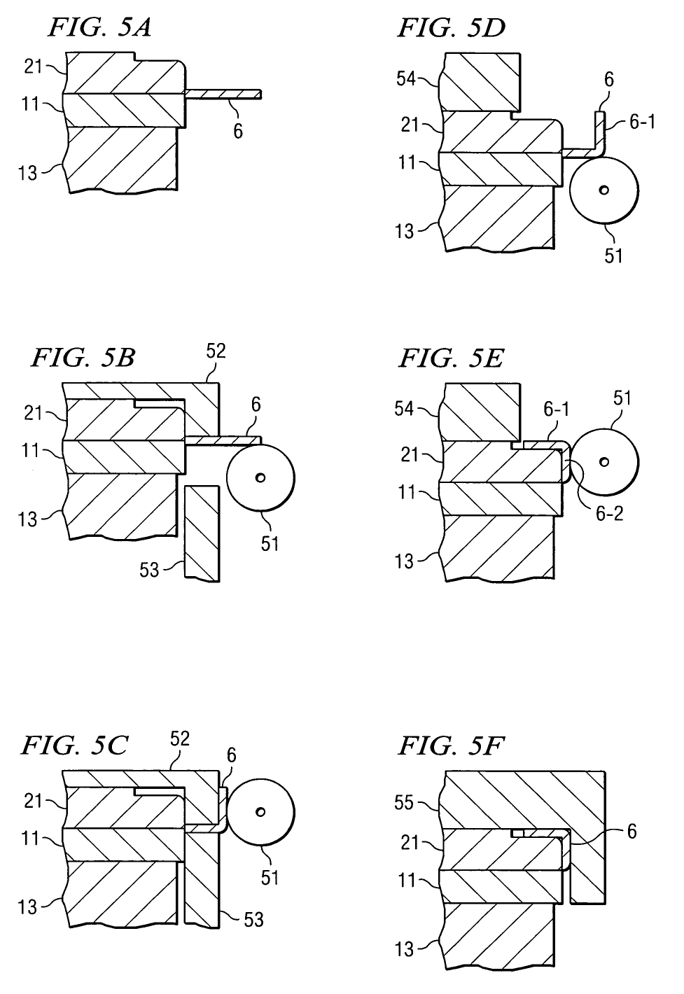

Ends 1, 2, 3, 4, 5 and 6 of terminals 14 and 15 are bent into position in one embodiment by roller forming rather than die-set forming as will be discussed with respect to FIGS. 5A through 5F. This effectively minimizes the package size and reduces the manufacturing costs. Having multiple terminal ends increases the flexibility since there are more terminals that can be utilized to apply power to different segments of the LED, if desired.

FIG. 1B is essentially the same as FIG. 1A except that reflector 16 is positioned around LED 12. Reflector 16 is helpful in situations where an LED dice is used in which light is emitted from the sides (and not just from the top) of the dice. When side light emitting LEDs are used the side reflector reflects the light to the top of the device. If light is desired to be emitted from one or more sides of the device, the reflector would only be on the sides where light is not desired so as to concentrate the light where it is most effective to perform the function desired. The light can be designed to come out of the top or the sides or both, if desired.

FIGS. 2A, 2B and 2C show the top, front and side views, respectively, of one embodiment of a molded structure 20 which has housing 22 surrounding the LED chip (not shown in FIGS. 2A, 2B or 2C). As discussed, one or more of these surfaces can be transparent to light while others can be opaque to light thereby allowing the diode to be constructed so that either all the light or some of the light comes out of any surface desired. In the embodiment of FIGS. 1A and 1B, terminal ends 1, 2 and 4 are connected to the anode while terminal ends 3, 5 and 6 are connected to the cathode. The dimensions shown in FIGS. 2A and 2B are for illustrative purposes only and the concepts discussed herein can be used with any dimensions desired.

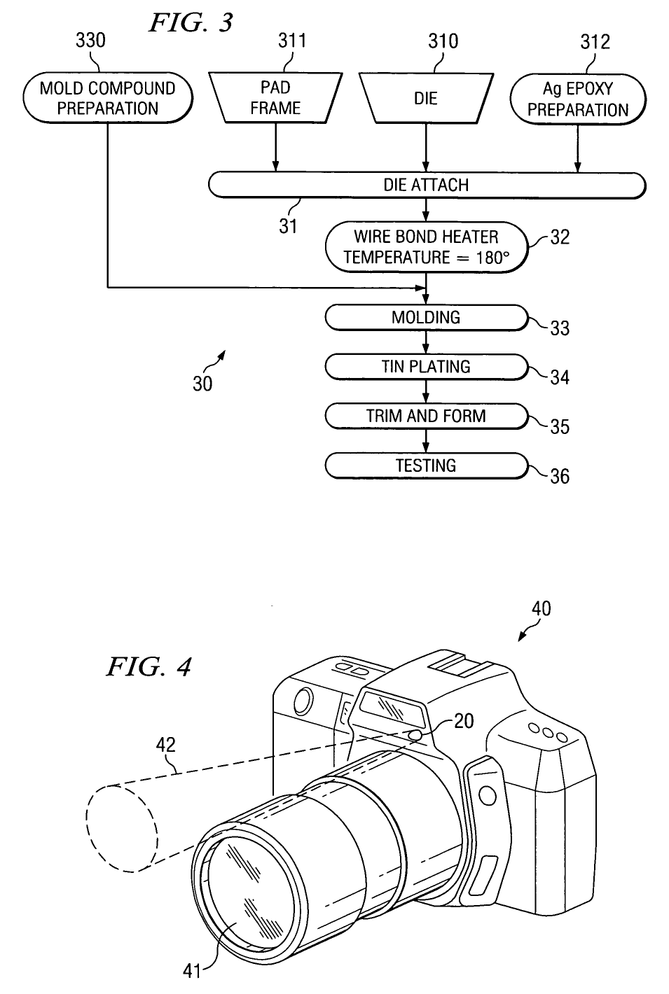

FIG. 3 shows one embodiment 30 of a flow chart of a manufacturing process for manufacturing LED 20. Process 310 shows the selection of an LED dice, such as dice 12 (FIG. 1A). Process 311 shows the lead frame being positioned. Process 31 bonds the selected LED dice to the pad (such as pad 65, FIG. 1A) using, for example, Ag epoxy (process 312).

Process 32 bonds LED wire 13 to terminal 15 (FIG. 1A). Process 330 prepares the molding compound (which, in one embodiment, can be molding epoxy formed using pellets of epoxy used for transfer molding). Process 33 forms the mold material around the LED which is attached to pad 65. The shape of the mold can be as desired for the function to be performed by the LED. Process 34 tin-plates the terminals. Process 35 trims and forms the terminals, (as will be discussed with respect to FIGS. 5A through 5F) while process 36 tests the device.

FIG. 4 shows one embodiment of electrical device 40 which in this case is a digital camera having lens 41 with diode 20 positioned near the lens. Diode 20 emits a beam of light 42 when activated. This light can be used to illuminate a subject (not shown) so that the camera can auto-focus itself prior to taking a picture.

FIG. 5A shows LED device portions 11 and 21 holding terminal 6 which has been sheared as discussed above with respect to FIG. 7A.

FIG. 5B shows supports 52 and 53 coming into position and in FIG. 5C roller 51 is shown slowly bending terminal 6 into a 90° bend. Since a rolling motion has been substituted for the quick shear force shown with respect to FIGS. 7A through 7J in the prior art the LED device does not need to have as much support for the bending process. This is shown with respect to FIG. 5D where support 54 holds the device in position while roller 51 slowly bends pre-bent terminal 6 into position as is shown in FIG. 5E where terminal end 6-1 is flat against the bottom surface of the substrate and terminal area 6-2 is flat against the side of the substrate thereby eliminating gap 66 (FIG. 6B).

FIG. 5F shows support 55 finishing the process by squaring terminal 6 so that it is flush against the side and bottom of portion 21 of the LED device.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An LED comprising:
a LED chip, said LED chip having at least two electrical inputs;
terminals electrically connected to each said LED electrical input, each said terminal having a plurality of end points; and
a molded casing formed around said LED chip, said molded casing such that the end points of said flat terminals overextend said casing and are folded around a bottom portion of said casing, said folding placing each of said terminals against the sides of said bottom portion of said casing.

2. The LED of claim 1 wherein said end-points of said terminals are folded against said molded casing using a roller.

3. The LED of claim 1 wherein light from said LED chip emits entirely out of a top surface of said LED chip.

4. The LED of claim 1 wherein light from said LED chip emits from a side surface of said LED chip.

5. The LED of claim 4 wherein a reflector is positioned around said LED chip to direct light from said side surface to a top surface of said molded casing.

6. An LED comprising:
an LED chip;
a molded housing surrounding said LED chip, said LED chip having N electrical connections; and
N essentially flat metal terminals positioned inside a bottom surface of said molded housing, each metal terminal having a plurality of end points said end points extending outside of said molded housing and folded flat against said molded housing; and
an electrical connection between each said terminal and each of said LED electrical connections.

7. The LED of claim 6 wherein light from said LED chip emits from a top surface of said LED chip.

8. The LED of claim 7 wherein light from said LED chip emits from at least one side surface of said LED chip as well as from said top surface.

9. The LED of claim 8 further comprising:
a reflector positioned between said LED chip and said housing, said reflector adapted to reflect light from said LED chip toward a top surface of said LED chip.

10. The LED of claim 6 wherein light from said LED chip emits entirely from a side surface of said auto-focus LED.

11. The LED of claim 10 further comprising:
a reflector positioned between said LED chip and said housing, said reflector adapted to reflect light from said LED chip toward a top surface of said LED chip.

12. The method of constructing a light source comprising:
forming at least one wire bond between an LED chip and a flat terminal strip;
forming a molded housing around said LED chip, said housing allowing at least a portion of said terminal strip to extend outside of said housing; and
roller bending said extended portion of said terminal strip so that said terminal strip is folded around an edge of said housing, said roller bending being performed without a die being positioned between said housing and said terminal.

13. The method of claim 12 wherein said flat terminal strip has a plurality of ends, each said end extending at least partially outside of said molded housing.

14. The method of claim 13 further comprising:
plating said terminal strip ends.

15. The method of claim 13 wherein said forming comprises:
creating a transparent surface at the top of said molded housing to allow light from said LED chip to emit through said molded housing.

16. A camera comprising:
an auto-focusing LED, said LED comprising:
a LED chip, said LED chip having at least two electrical inputs; terminals electrically connected to each said LED electrical input, each said terminal having a plurality of end points; and
a molded casing formed around said LED chip, said molded casing such that the end points of said flat terminals overextend said casing and are folded around bottom portion of said casing, said fold placing each of said terminally against the sides of said bottom portion of said casing.

17. The LED of claim 16 wherein said end-points of said terminals are folded against said molded casing using a roller.

18. The method of manufacturing an LED, said method comprising:
attaching an LED chip to a support surface;
said support surface including at least two elongated terminal strips, each terminal strip having a plurality of ends;
bonding an electrical connector from a top surface of said LED chip to one of said terminals;
created a molded housing around said LED chip, said housing allowing the ends of said terminals to extend beyond the boundaries of said housing; and
forming, under control of a roller, said extended portion of said terminals such that said formed terminal portions are bent flat against said housing boundary.

19. The method of claim 18 further comprising:
tin plating said extended portion of said terminals prior to said forming.

20. The method of claim 19 in sorting said LED into a digital camera such that said LED is capable of performing the auto-focusing function of said camera.
